(19) United States
(12) Patent Application Publication
(10) Pub. No.: US 2024/0089667 A1
(43) Pub. Date: Mar. 14, 2024

(54) TRANSDUCER, ELECTRONIC DEVICE, AND TRANSDUCER ARRAY

(71) Applicant: ROHM CO., LTD., Kyoto (JP)

(72) Inventor: Takashi NAIKI, Kyoto (JP)

(73) Assignee: ROHM CO., LTD., Kyoto (JP)

(21) Appl. No.: 18/514,288

(22) Filed: Nov. 20, 2023

Related U.S. Application Data
(63) Continuation of application No. PCT/JP2022/020960, filed on May 20, 2022.

(30) Foreign Application Priority Data
May 31, 2021 (JP) 2021-091440

(51) Int. Cl. H04R 17/00; H10N 39/00

(52) U.S. Cl. CPC H04R 17/00; H10N 39/00

(57) ABSTRACT

A transducer includes: a substrate including a main surface and a back surface facing the main surface; a plurality of vibrating films formed in the substrate at a predetermined thickness between the main surface and a plurality of recesses formed in the back surface of the substrate such that the main surface can vibrate in the thickness direction of the substrate; and a plurality of driving layers laminated on the plurality of vibrating films, each being constituted by a pair of electrode layers of a lower electrode layer and an upper electrode layer with a piezoelectric layer therebetween and being disposed on the main surface, in which the plurality of vibrating films include vibrating films arranged at predetermined intervals in each of at least two directions in a plane of the main surface, and the transducer generate sufficient sound volume because the transducer is used as a speaker.

### CROSS-REFERENCE TO RELATED APPLICATION

This disclosure is a continuation application of International Application No. PCT/JP2022/020960, filed on May 20, 2022, which claims the priority of Japanese Patent Application No. 2021-091440, filed on May 31, 2021, the entire contents of which are incorporated by reference herein.

### TECHNICAL FIELD

The present disclosure relates to a transducer, an electronic device, and a transducer array.

### BACKGROUND ART

There is a conventionally known transducer that transmits or receives sound waves or ultrasound waves. For example, a transducer is provided as a speaker that generates sound waves. The transducer is fabricated using a micro electro mechanical systems (MEMS) technology based on a semiconductor manufacturing technology and includes a piezoelectric element which has a piezoelectric film interposed between a pair of electrodes and drives a vibrating plate (see, for example, JP 2012-105170 A).

### BRIEF DESCRIPTION OF THE DRAWINGS

FIG. 1 is a plan view of a transducer of the present embodiment.

FIG. 2 is a cross sectional view of the transducer of the present embodiment.

FIG. 3 is a plan view showing the arrangement of vibrating films at a main surface of a substrate in the transducer of the present embodiment.

FIG. 4 is a cross sectional view of a transducer of a first modified example.

FIG. 5 is a cross sectional view of a transducer of a second modified example.

FIG. 6 is a cross sectional view of a transducer of a third modified example.

FIG. 7 is a plan view of a transducer of a fourth modified example.

FIG. 8 is a cross sectional view of the transducer of the fourth modified example.

FIG. 9 is a plan view showing the arrangement of vibrating films at a main surface of a substrate in the transducer of the fourth modified example.

FIG. 10 is a plan view of a transducer of a fifth modified example.

FIG. 11 is a cross sectional view of the transducer of the fifth modified example.

FIG. 12 is a plan view showing the arrangement of vibrating films at a main surface of a substrate in the transducer of the fifth modified example.

FIG. 13 is a plan view of a transducer of a sixth modified example.

FIG. 14 is a cross sectional view of the transducer of the sixth modified example.

FIG. 15 is a plan view showing the arrangement of vibrating films at a main surface of a substrate in the transducer of the sixth modified example.

FIG. 16 is a block diagram of an electronic device.

FIG. 17 is a plan view of a transducer array.

FIG. 18 is a cross sectional view of the transducer array.

FIG. 19 is a plan view of a modified example of a transducer array.

### DETAILED DESCRIPTION

Next, the present embodiment will be described with reference to the drawings. In descriptions of the drawings below, the same or similar parts are denoted by the same or similar reference numerals. It should be noted, however, that the drawings are schematic, and that the relationships between the thicknesses and the planar dimensions of each component and the like are different from those in reality. Therefore, specific thicknesses and dimensions should be determined with reference to the following description. In addition, it is needless to say that the drawings include portions in which the relationships and the ratios of the dimensions are different from each other.

Further, the following embodiment makes an exemplification for embodying a technical idea, and does not specify the material, shape, structure, disposition, and the like of each component. In the embodiment, various modifications can be made within the scope of the claims.

### Transducer

A transducer of the present embodiment is manufactured using an MEMS technology and is intended to be used as a speaker that generates sound waves. The transducer of the present embodiment has the following configuration.

A transducer includes: a substrate including a main surface and a back surface facing the main surface; a plurality of vibrating films formed in the substrate at a predetermined thickness between the main surface and a plurality of recesses formed in the back surface of the substrate such that the main surface can vibrate in the thickness direction of the substrate; and a plurality of driving layers laminated on the plurality of vibrating films, each being constituted by a pair of electrode layers with a piezoelectric layer therebetween and being disposed on the main surface, and the plurality of vibrating films include vibrating films arranged at predetermined intervals in each of at least two directions in a plane of the main surface. The sound volume generated by the transducer can be ensured by arranging the vibrating films such that the vibrating films occupy the most part of the main surface.

The vibrating films arranged at the predetermined intervals in each of the at least two directions may include vibrating films arranged at equal intervals in each of three directions including the at least two directions in the plane of the main surface. The sound volume generated by the transducer can be ensured by arranging the vibrating films while ensuring the density of the vibrating films.

The plurality of vibrating films may include vibrating films that are arranged such that an interval between mutually adjacent vibrating films is equal in the plane of the main surface. The sound volume generated by the transducer can be ensured by arranging the vibrating films while ensuring the density of the vibrating films.

Natural frequencies of the plurality of vibrating films may be higher than an audible frequency band. Since the natural frequencies are not within a frequency range of the audible frequency band, there is no deterioration in sound quality caused by the natural frequencies of the vibrating films in the audible frequency band.

The plurality of vibrating films may include vibrating films having the same shape in the plane of the main surface. This can facilitate the design, manufacturing, and the like of a transducer.

Wiring may be connected to the pair of electrode layers in each of the plurality of driving layers from an electrode pad such that a voltage for driving the driving layers is supplied. The plurality of driving layers are driven by a voltage supplied from wiring connected to the pair of electrode layers.

The wiring may include common wiring toward the pair of electrode layers in each of the plurality of driving layers. The driving layers connected to the common wiring may be driven synchronously.

The plurality of vibrating films may include vibrating films with equal intervals from one vibrating film in the plane of the main surface. By arranging the vibrating films so as to have equal intervals from one vibrating film as a reference, the vibrating films can be arranged while ensuring the density of the vibrating films.

The vibrating films with the equal intervals from the one vibrating film may be arranged at predetermined intervals along a periphery that is at predetermined intervals from the one vibrating film. The plurality of vibrating films can be arranged such that vibrating films of a first periphery surround the one vibrating film as a reference.

The vibrating films may include vibrating films that are arranged at predetermined intervals along a second periphery ((n+1)-th periphery) at predetermined intervals from the one vibrating film, the second periphery ((n+1)-th periphery) being located outside of a first periphery (n-th periphery: n=1, 2, 3 . . . ) which is at predetermined intervals from the one vibrating film and along which vibrating films are arranged at predetermined intervals. The vibrating films of the second periphery are arranged so as to surround the vibrating films of the first periphery, and by repeating this kind of arrangement, it is possible to sequentially arrange vibrating films from the vibrating films of the first periphery surrounding the one vibrating film as a reference to vibrating films of a desired periphery ((n+1)-th periphery).

The plurality of vibrating films may include vibrating films having the same shape of each periphery in the plane of the main surface. It is possible to set characteristics of vibrating films of each periphery.

The wiring may include wiring common to vibrating films disposed along each periphery. Driving layers of each periphery connected to the common wiring can be driven synchronously.

On the back surface, a partition wall may be formed from the back surface to a predetermined height around each of the recesses on each vibrating film of the plurality of vibrating films to form an independent space. It is possible to suppress the diffraction of sound waves emitted from the plurality of vibrating films toward the back surface in a direction of the main surface and reduce the deterioration in sound quality.

On the main surface, a partition wall may be formed from the main surface to a predetermined height around each vibrating film of the plurality of vibrating films to form an independent space. Sound waves emitted from the plurality of vibrating films on the main surface can be efficiently emitted toward the front of the main surface.

The substrate may be constituted by a silicon substrate. The transducer can be fabricated using an MEMS technology.

The transducer may further include another substrate that is disposed to face the back surface and is mounted near the back surface of the substrate. The other substrate can provide various functions such as supporting the substrate or forming a cavity near the back surface of the substrate.

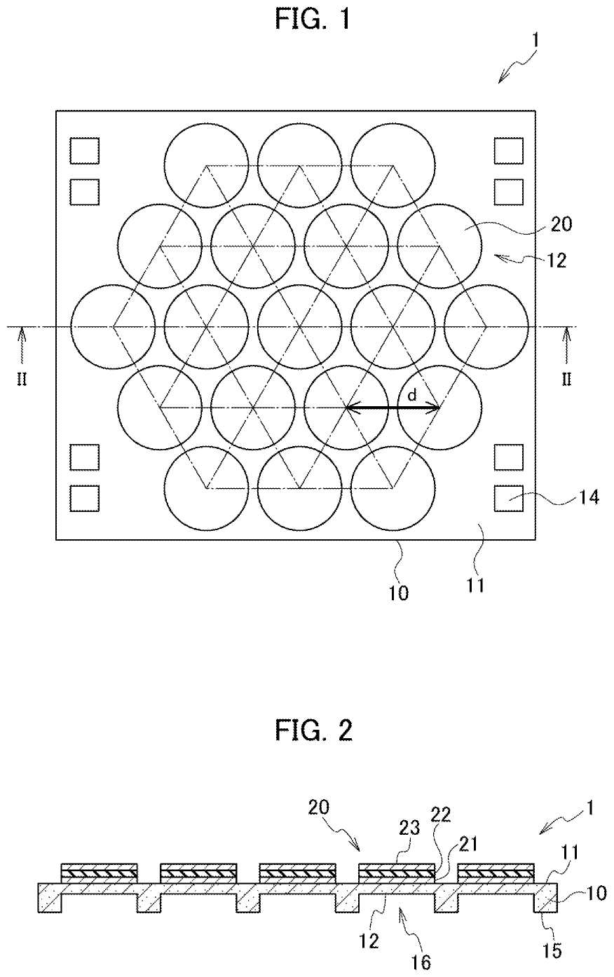

FIG. 1 is a plan view showing a transducer 1 of the present embodiment. FIG. 2 is a cross sectional view showing the transducer 1 of the present embodiment. The cross sectional view of FIG. 2 shows a cross section of the transducer 1 which is taken along a section line II-II in the plan view of FIG. 1. The transducer 1 of the present embodiment is formed on a substrate 10 having a flat main surface 11 and a back surface 15 facing the main surface 11. The substrate 10 is a silicon substrate with a predetermined thickness and an approximate plate shape and has an approximate square shape in which the size in a vertical direction and the size in a horizontal direction are approximately equal in plan view. The substrate 10 is not limited to a silicon substrate, but may be a glass substrate or made of other kinds of materials such as organic materials.

A plurality of recesses 16 are formed in the back surface 15 of the substrate 10. The plurality of recesses 16 are formed so as to reach a predetermined depth from the main surface 11 and leave the substrate 10 of a predetermined thickness such that the main surface 11 can vibrate in a thickness direction of the substrate 10. The portions where the substrate 10 of the predetermined thickness is left form a plurality of vibrating films 12. Since the plurality of vibrating films 12 are used to generate sound waves of speakers, natural frequencies of the vibrating films 12 are set to be higher than an audible frequency band. In addition, although the main surface 11 of the substrate 10 constituting the plurality of vibrating films 12 is connected to each of the vibrating films 12 at the whole periphery thereof, appropriate slits may be formed in the substrate 10 to achieve a structure of a cantilever beam or a double fixed beam of each vibrating film 12.

At each of the plurality of vibrating films 12, on the main surface 11, a driving layer 20 is laminated, the driving layer 20 being constituted by a pair of electrode layers of a lower electrode layer 21 and an upper electrode layer 23 with a piezoelectric layer 22 therebetween. Each driving layer 20 constitutes a piezoelectric element that drives each vibrating film 12 to vibrate in the thickness direction of the substrate 10 due to a voltage supplied by a wiring layer (not shown). At the main surface 11, the plurality of vibrating films 12 have an approximate disk shape with the same diameter. The driving layers 20 laminated on the plurality of vibrating films 12 at the main surface 11 similarly have an approximate disk shape in accordance with the shape of the plurality of vibrating films 12.

The plurality of vibrating films 12 are arranged at equal intervals d in three directions at the main surface 11. The intervals d of the vibrating films 12 refer to distances between centers of the vibrating films 12 having an approximate disk shape. In general, the intervals d of the vibrating films 12 may be distances between centers of gravity of the vibrating films 12 at the main surface 11. At the main surface 11, the plurality of vibrating films 12 are arranged at equal intervals d in three directions, and therefore the plurality of vibrating films 12 have a symmetry in which the other vibrating film 12 adjacent to each vibrating film 12 is located at a 6-fold rotationally symmetric position of each vibrating film 12. The equal intervals d are not strictly limited to equal intervals, but may be intervals that can be regarded as approximately equal, such as the difference being limited to about ±10%.

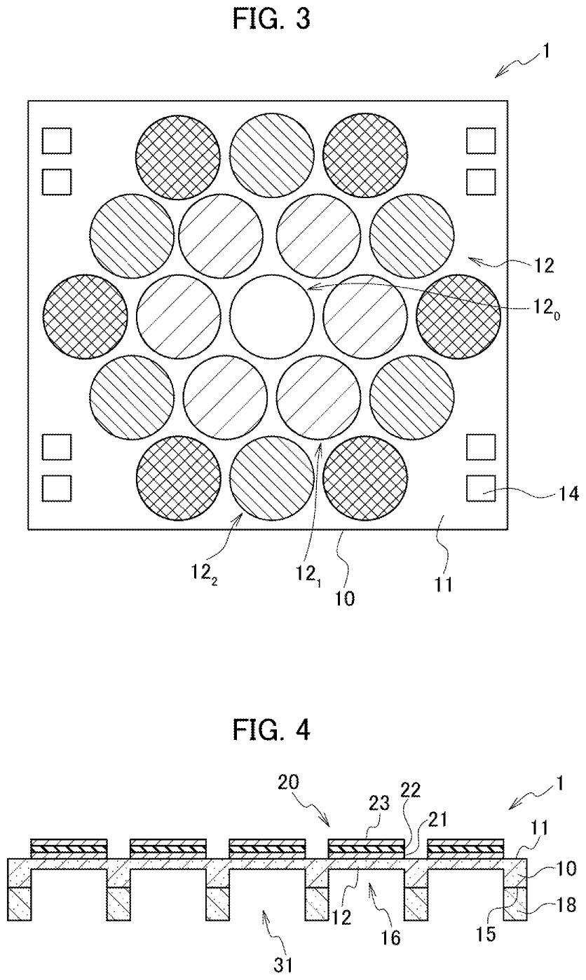

FIG. 3 is a plan view showing the arrangement of the vibrating films 12 at the main surface 11 of the substrate 10 in the transducer 1. One vibrating film 12 arranged in the center of the main surface 11 will be referred to as a central vibrating film 120. The plurality of vibrating films 12 have six vibrating films 12 that are adjacent to the central vibrating film 120 and are arranged at predetermined intervals on a periphery at predetermined intervals from the central vibrating film 120, which surrounds the central vibrating film 120. These six vibrating films 12 will be referred to as vibrating films 121 of a first periphery.

Further, the plurality of vibrating films 12 have 12 vibrating films 12 arranged so as to surround the vibrating films 12 of the first periphery such that six vibrating films 12 are located at six positions, each being adjacent to and around each of the vibrating films 121 of the first periphery and being a 6-fold rotationally symmetric position of each of the vibrating film 121 of the first periphery. Out of these 12 vibrating films 12, six vibrating films 12 having relatively small intervals with the central vibrating film 120 will be referred to as vibrating films 122 of a second periphery, and six vibrating films 12 having relatively large intervals with the central vibrating film 120 will be referred to as vibrating films 123 of a third periphery.

The vibrating films 122 of the second periphery are arranged at predetermined intervals on the periphery at predetermined intervals from the central vibrating film 120 so as to surround the vibrating films 121 of the first periphery. The vibrating films 123 of the third periphery are arranged at predetermined intervals on the periphery at predetermined intervals from the central vibrating film 120 so as to surround the vibrating films 122 of the second periphery. The most part of the main surface 11 is occupied by the central vibrating film 120, the vibrating films 121 of the first periphery, the vibrating films 122 of the second periphery, and the vibrating films 123 of the third periphery.

A plurality of electrode pads 14 are formed along a pair of sides individually extending in a vertical direction of the main surface 11 and are formed at portions which are near four vertices of the main surface 11 having an approximate square shape in plan view and at which the vibrating films 12 are not arranged. From the plurality of electrode pads 14, wiring (not shown) is connected to the pair of electrode layers of the lower electrode layer 21 and the upper electrode layer 23 in each driving layer 20 so as to be able to supply voltages to the plurality of driving layers 20 that drive the plurality of vibrating films 12 individually. From the plurality of electrode pads 14, common wiring is connected to the plurality of driving layers 20.

The connection of wiring from the pair of electrode pads 14 to the plurality of driving layers 20 is not limited thereto, and wiring may be independently connected such that some of the plurality of vibrating films 12 formed at the main surface 11 are individually controlled. For example, wiring toward driving layers 20 for driving vibrating films 12 is common, that is wiring toward driving layers 20 for driving the vibrating films 121 of the first periphery arranged at the main surface 11 is common, wiring toward driving layers 20 for driving the vibrating films 122 of the second periphery is common, and wiring toward driving layers 20 for driving the vibrating films 122 of the third periphery is common, and wiring may be connected so as to be able to drive the central vibrating film 120, the vibrating films 121 of the first periphery, the vibrating films 122 of the second periphery, and the vibrating films 122 of the third periphery independently. In addition, wiring toward the driving layers 20 for driving the plurality of vibrating films 12 disposed at the main surface 11 may be independently connected so as to be able to drive the vibrating films 12 individually. By independently controlling at least some of the plurality of vibrating films 12 formed at the main surface 11, it is possible to provide various functions such as the interference between sound waves generated in different phases, for example.

In the transducer 1 of the present embodiment, the most part of the main surface 11 is occupied by the plurality of vibrating films 12 due to the vibrating films 12 with an approximate disk shape of the same diameter being arranged at equal intervals d in three directions at the main surface 11. Due to this arrangement, the other vibrating film adjacent to each vibrating film 12 is located at a 6-fold rotationally symmetric position of each vibrating film 12, and therefore the vibrating films 12 can be arranged with a high density. Accordingly, the most part of the main surface 11 can be effectively used as the vibrating films 12, and the transducer 1 can generate sufficient sound volume when used as a speaker. Further, since the transducer 1 of the present embodiment is manufactured using an MEMS technology based on a semiconductor manufacturing technology, a plurality of pieces can be fabricated at a time with high accuracy.

In the transducer 1 of the present embodiment, the plurality of vibrating films 12 at the main surface 11 are arranged at equal intervals in three directions, but the arrangement is not limited thereto, and the plurality of vibrating films 12 may be arranged at equal intervals in two directions. In such a case also, the density of the plurality of vibrating films 12 at the main surface 11 can be ensured, and the plurality of vibrating films 12 can be formed at the most part of the main surface 11.

Further, in the transducer 1 of the present embodiment, it is assumed that the plurality of vibrating films 12 are constituted by the central vibrating film 120, the vibrating films 121 of the first periphery, the vibrating films 122 of the second periphery, and the vibrating films 123 of the third periphery, but the present invention is not limited thereto, and the plurality of vibrating films 12 may be constituted by vibrating films from the central vibrating film 120 to vibrating films 12 of a desired periphery. Vibrating films 12 constituting one periphery (n-th periphery: n=1, 2, 3 . . . ) are arranged, and then vibrating films 12 which are adjacent to the vibrating films of the n-th periphery and constitute a next periphery ((n+1)-th periphery) are arranged, and by repeating this kind of arrangement, it is possible to arrange vibrating films from the central vibrating film to vibrating films 12 of a desired periphery.

In the present embodiment, it is assumed that the plurality of vibrating films 12 arranged at the main surface 11 have an approximate disk shape with the same diameter, but the present invention is not limited thereto. For example, the plurality of vibrating films 12 may have the same predetermined shape, at least a part of the vibrating films 12 may have the same shape, or all of the vibrating films 12 may have different shapes. For example, vibrating films 12 constituting each periphery may have the same shape, similar to the central vibrating film 120, the vibrating films 121 of the first periphery, the vibrating films 122 of the second periphery, and the vibrating films 123 of the third periphery. For example, the central vibrating film 120, the vibrating films 121 of the first periphery, the vibrating films 122 of the second periphery, and the vibrating films 123 of the third periphery may have an approximate disk shape with different diameters. Since the plurality of driving layers 20 are laminated on the plurality of vibrating films 12, the driving layers 20 may have the same shape as each of the plurality of vibrating films 12 on which the driving layers 20 are laminated.

### First Modified Example

FIG. 4 is a cross sectional view showing a transducer 1 of a first modified example. The transducer 1 of the first modified example differs from the transducer 1 of the present embodiment in that lower partition walls 18 are formed from a back surface 15 of a substrate 10 to a predetermined height so as to surround a plurality of recesses 16 formed in the back surface 15. Since other configurations are the same as those of the transducer 1 of the present embodiment, the corresponding members are denoted with the same reference numerals to clarify the correspondence relationship.

The plurality of recesses 16 are formed in the back surface 15 of the substrate 10. The plurality of recesses 16 are formed so as to reach a predetermined depth from a main surface 11 and leave the substrate 10 of a predetermined thickness such that the main surface 11 can vibrate in a thickness direction of the substrate 10. The portions where the substrate 10 of the predetermined thickness is left form a plurality of vibrating films 12.

On the back surface 15, the lower partition walls 18 are formed from the back surface 15 to a predetermined height by surrounding the plurality of recesses 16. By means of each lower partition wall 18, a lower chamber 31 is formed, which reaches the top of each lower partition wall 18 at a predetermined height from the back surface 15, from each vibrating film 12 formed on a bottom surface of each of the plurality of recesses 16. Sound waves emitted toward the back surface 15 from each vibrating film 12 formed on a bottom surface of each of the plurality of recesses 16 are guided in a direction of each lower chamber 31 formed by means of each lower partition wall 18. This suppresses the diffraction of sound waves emitted from the plurality of vibrating films 12 toward the back surface 15 in a direction of the main surface 11 and reduces the deterioration in sound quality caused by the diffraction of sound waves emitted from the plurality of vibrating films 12 at the main surface 11.

Although it is assumed that the lower partition walls 18 on the back surface 15 are formed so as to surround the plurality of recesses 16 individually, the present invention is not limited thereto, and each lower partition wall 18 on the back surface 15 may be formed so as to surround several recesses 16 collectively. For example, the vibrating films 121 of the first periphery shown in FIG. 3 may be collectively surrounded and a common lower chamber 31 may be formed therefor, the vibrating films 122 of the second periphery may be collectively surrounded and a common lower chamber 31 may be formed therefor, and the vibrating films 123 of the third periphery may be collectively surrounded and a common lower chamber 31 may be formed therefor. Further, the lower partition walls 18 formed along the outer periphery of the back surface 15 so as to surround all of the recesses 16 formed in the back surface 15 may form one common lower chamber 31. Even in such a case, sound waves emitted from the vibrating films 12 formed on the bottom surfaces of the plurality of recesses 16 toward the back surface 15 are guided in the direction of the lower chambers 31 by means of the lower partition walls 18. This suppresses the diffraction of sound waves in a direction of the main surface 11 and reduces deterioration in sound quality caused by the diffraction.

Each lower partition wall 18 may be fabricated by attaching, to the back surface 15 of the substrate 10, a silicon substrate with a predetermined thickness having a through hole formed at a predetermined position thereof. Each lower partition wall 18 is not limited to a silicon substrate, but may be a glass substrate or made of other kinds of materials such as organic materials. In addition, one silicon substrate may be prepared, and the lower partition walls 18 and the recesses 16 may be continuously formed by means of etching.

### Second Modified Example

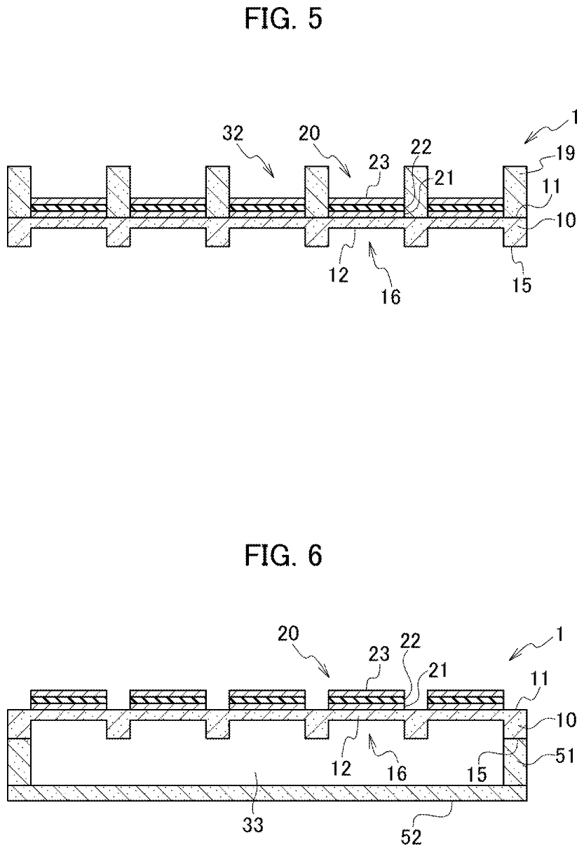

FIG. 5 is a cross sectional view showing a transducer 1 of a second modified example. The transducer 1 of the second modified example differs from the transducer 1 of the present embodiment in that upper partition walls 19 are formed from a main surface 11 of a substrate 10 to a predetermined height so as to surround a plurality of vibrating films 12 formed on the main surface 11. Since other configurations are the same as those of the transducer 1 of the present embodiment, the corresponding members are denoted with the same reference numerals to clarify the correspondence relationship.

A plurality of recesses 16 are formed in a back surface 15 of the substrate 10. The plurality of recesses 16 are formed so as to reach a predetermined depth from the main surface 11 and leave the substrate 10 of a predetermined thickness such that the main surface 11 can vibrate in a thickness direction of the substrate 10. The portions where the substrate 10 of the predetermined thickness is left form the plurality of vibrating films 12.

On the main surface 11, the upper partition walls 19 are formed from the main surface 11 to a predetermined height by surrounding the plurality of vibrating films 12 and a plurality of driving layers 20 laminated on the plurality of vibrating films 12. By means of each upper partition wall 19, an upper chamber 32 is formed, which reaches the top of each upper partition wall 19 at a predetermined height, from each of the plurality of vibrating films 12 on the main surface 11. Sound waves emitted from each vibrating film 12 on the main surface 11 are guided in a direction of each upper chamber 32 by means of each upper partition wall 19. Therefore, sound waves emitted from the plurality of vibrating films 12 on the main surface 11 are efficiently emitted toward the front of the main surface 11.

Although it is assumed that each upper partition wall 19 is formed to surround each of the plurality of vibrating films 12 on the main surface 11, the present invention is not limited thereto, and each upper partition wall 19 may be formed to collectively surround several vibrating films 12 on the main surface 11. For example, the vibrating films 121 of the first periphery shown in FIG. 3 may be collectively surrounded and a common upper chamber 32 may be formed therefor, the vibrating films 122 of the second periphery may be collectively surrounded and a common upper chamber 32 may be formed therefor, and the vibrating films 123 of the third periphery may be collectively surrounded and a common upper chamber 32 may be formed therefor. Further, the upper partition walls 19 formed along the outer periphery of the main surface 11 so as to surround all of the vibrating films 12 on the main surface 11 may form one common upper chamber 32. In such a case also, sound waves emitted from the plurality of vibrating films 12 are guided in a direction of the upper chambers 32 formed by means of the upper partition walls 19 and are efficiently emitted toward the front of the main surface 11.

Each upper partition wall 19 may be fabricated by attaching, to the main surface 11 of the substrate 10, a silicon substrate with a predetermined thickness having a through hole formed at a predetermined position thereof. Each upper partition wall 19 is not limited to a silicon substrate, but may be a glass substrate or made of other kinds of materials such as organic materials. In addition, one silicon substrate may be prepared, and the upper partition walls 19 may be formed by means of etching.

In the second modified example, it is assumed that the upper partition walls 19 are formed from the main surface 11 to a predetermined height to surround the plurality of vibrating films 12 formed on the main surface 11 of the substrate 10, but lower partition walls 18 may be further formed from the back surface 15 to a predetermined height to surround the plurality of recesses 16 formed in the back surface 15. In such a case, sound waves emitted from the plurality of vibrating films 12 are guided in the direction of the upper chambers 32 formed by means of the upper partition walls 19 and are efficiently emitted toward the front of the main surface 11. In addition, sound waves emitted from the vibrating films 12 formed on bottom surfaces of the plurality of recesses 16 toward the back surface 15 are guided in the direction of the lower chambers 31 by means of the lower partition walls 18. This suppresses diffraction of sound waves in the direction of the main surface 11 and reduces deterioration in sound quality caused by the diffraction.

### Third Modified Example

FIG. 6 is a cross sectional view showing a transducer 1 of a third modified example. The transducer 1 of the third modified example differs from the transducer 1 of the present embodiment in that the transducer 1 of the third modified example has sides walls 51 formed to a predetermined height from a back surface 15 of a substrate 10 along the outer periphery, and a second substrate 52 which is attached to the top of the side walls 51 and has an approximate square shape similar to that of the substrate 10 in plan view. Since other configurations are the same as those of the transducer 1 of the present embodiment, the corresponding members are denoted with the same reference numerals to clarify the correspondence relationship.

A plurality of recesses 16 are formed in the back surface 15 of the substrate 10. The plurality of recesses 16 are formed so as to reach a predetermined depth from a main surface 11 and leave the substrate 10 of a predetermined thickness such that the main surface 11 can vibrate in a thickness direction of the substrate 10. The portions where the substrate 10 of the predetermined thickness is left form a plurality of vibrating films 12.

On the back surface 15, the side walls 51 with a predetermined thickness inward from the outer periphery thereof are formed from the back surface 15 to a predetermined height. The second substrate 52 having an approximate square shape similar to that of the substrate 10 in plan view is attached to the top of the side walls 51 having the predetermined height from the back surface 15. A cavity 33 sealed by the side walls 51 and the second substrate 52 is formed at the back surface 15 of the substrate 10.

Sound waves emitted from the vibrating films 12 formed on bottom surfaces of the plurality of recesses 16 formed in the back surface 15, toward the back surface 15 are trapped in the sealed cavity 33 and the leakage of the sound waves to the outside is suppressed. Therefore, with respect to sound waves emitted from the plurality of vibrating films 12 formed on the bottom surfaces of the plurality of recesses 16, diffraction of the sound waves in the direction of the main surface 11 is suppressed, and deterioration in sound quality caused by the diffraction of the sound waves generated from the plurality of vibrating films 12 on the main surface 11 is reduced.

Each side wall 51 may be fabricated by attaching, to the back surface 15 of the substrate 10, a silicon frame member with a predetermined thickness having a through hole formed at a predetermined position thereof. The material of the side walls 51 is not limited to silicon, but the side walls may be made of other kinds of materials such as glass and organic materials. In addition, one silicon substrate may be prepared, and the side walls 51 and the recesses 16 may be continuously formed by means of etching. Similar to the substrate 10, the second substrate 52 may be a silicon substrate, made of other kinds of materials such as glass or organic materials, or may be a printed substrate.

Although it is assumed that the cavity 33 sealed by the side walls 51 and the second substrate 52 is formed in the back surface 15 of the substrate 10, the present invention is not limited thereto, and the cavity 33 may not be sealed or the cavity 33 may not be formed. Further, although it is assumed that the side walls 51 are formed to a predetermined height on the back surface 15, and the second substrate 52 is attached to the top of the back surface 15, the present invention is not limited thereto, and the side walls 51 may not be disposed on the back surface 15, and the second substrate 52 may be attached to the back surface 15 by means of appropriate means. In such a case also, various functions can be provided, such as suppressing diffraction of sound waves in the direction of the main surface 11 by means of the second substrate 52, and providing driving circuits for the plurality of driving layers 20 on the second substrate 52, the sound waves being emitted in the direction of the back surface 15 from the plurality of vibrating films 12 formed on the bottom surfaces of the plurality of recesses 16.

### Fourth Modified Example

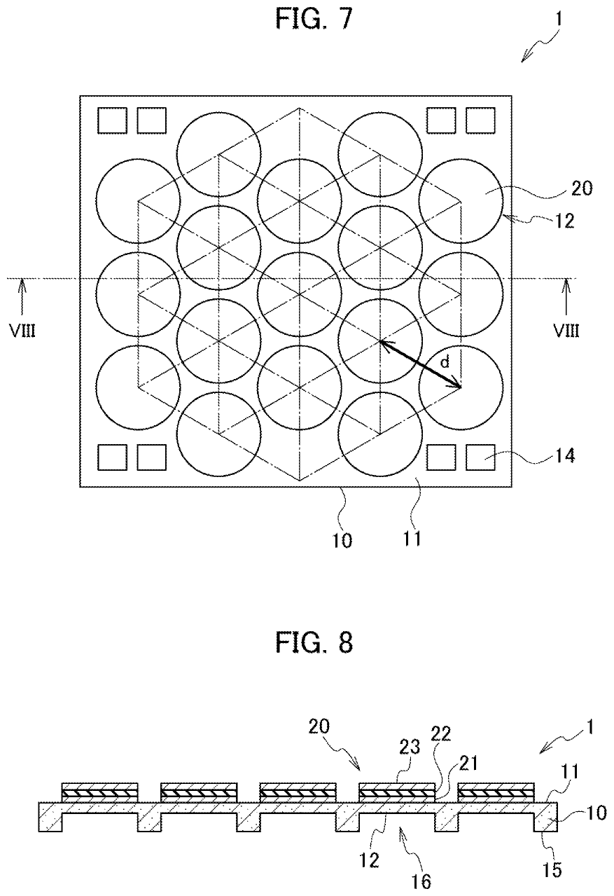

FIG. 7 is a plan view showing a transducer 1 of a fourth modified example. FIG. 8 is a cross sectional view showing the transducer 1 of the fourth modified example. The cross sectional view of FIG. 8 shows a cross section of the transducer 1 which is taken along a section line VIII-VIII in the plan view of FIG. 7. Compared with the transducer 1 of the present embodiment, the transducer 1 of the fourth modified example has a different arrangement of a plurality of vibrating films 12 and a plurality of electrode pads 14 at a main surface 11 of a substrate 10. Since other configurations are the same as those of the transducer 1 of the present embodiment, the corresponding members are denoted with the same reference numerals to clarify the correspondence relationship.

The transducer 1 of the fourth modified example is formed on the substrate 10 having the main surface 11 that is flat and a back surface 15 facing the main surface 11. The substrate 10 is a silicon substrate with a predetermined thickness and an approximate plate shape and has an approximate square shape in which the size in a vertical direction and the size in a horizontal direction are approximately equal in plan view. The substrate 10 is not limited to a silicon substrate, but may be a glass substrate or made of other kinds of materials such as organic material.

A plurality of recesses 16 are formed in the back surface 15 of the substrate 10. The plurality of recesses 16 are formed so as to reach a predetermined depth from the main surface 11 and leave the substrate 10 of a predetermined thickness such that the main surface 11 can vibrate in a thickness direction of the substrate 10. The portions where the substrate 10 of the predetermined thickness is left form a plurality of vibrating films 12. Since the plurality of vibrating films 12 are used to generate sound waves of speakers, natural frequencies of the vibrating films 12 are set to be higher than an audible frequency band. In addition, although the main surface 11 of the substrate 10 constituting the plurality of vibrating films 12 is connected to each of the vibrating films 12 at the whole periphery thereof, appropriate slits may be formed in the substrate 10 to achieve a structure of a cantilever beam or a double fixed beam of each vibrating film 12.

At each of the plurality of vibrating films 12, on the main surface 11, a driving layer 20 is laminated, the driving layer 20 being constituted by a pair of electrode layers of a lower electrode layer 21 and an upper electrode layer 23 with a piezoelectric layer 22 therebetween. Each driving layer 20 constitutes a piezoelectric element that drives each vibrating film 12 to vibrate in the thickness direction of the substrate 10 due to a voltage supplied by a wiring layer (not shown). At the main surface 11, the plurality of vibrating films 12 have an approximate disk shape with the same diameter. The driving layers 20 laminated on the vibrating films 12 similarly have an approximate disk shape in accordance with the shape of the plurality of vibrating films 12.

The plurality of vibrating films 12 are arranged at equal intervals d in three directions at the main surface 11. Therefore, the plurality of vibrating films 12 have a symmetry in which the other vibrating film 12 adjacent to each vibrating film 12 is located at a 6-fold rotationally symmetric position of each vibrating film 12. The equal intervals d are not strictly limited to equal intervals, but may be intervals that can be regarded as approximately equal, such as the difference being limited to about ±10%.

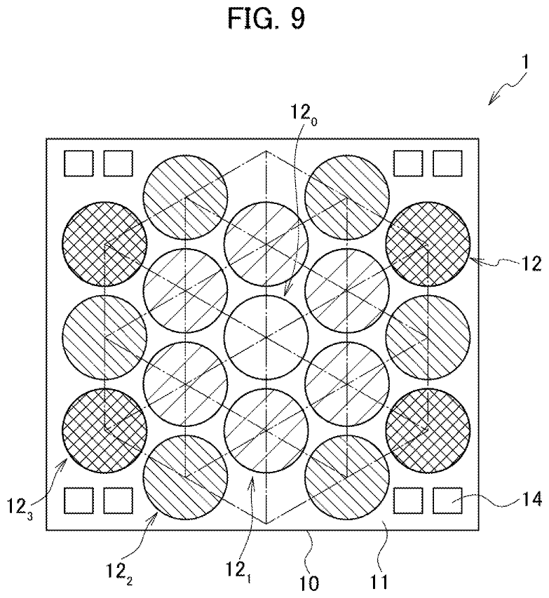

FIG. 9 is a plan view showing an arrangement of the vibrating films 12 at the main surface 11 of the substrate 10 in the transducer 1. One vibrating film 12 arranged in the center of the main surface 11 will be referred to as a central vibrating film 120. The plurality of vibrating films 12 have six vibrating films 12 that are adjacent to the central vibrating film 120 and are arranged at predetermined intervals on a periphery at predetermined intervals from the central vibrating film 120, which surrounds the central vibrating film 120. These six vibrating films 12 will be referred to as vibrating films 121 of a first periphery.

In addition, the plurality of vibrating films 12 have ten vibrating films 12 arranged so as to surround the vibrating films 12 of the first periphery such that a vibrating film 12 adjacent to and around each of the vibrating films 121 of the first periphery is located at a 6-fold rotationally symmetric position of each of the vibrating films 121 of the first periphery. Out of the ten vibrating films 12, six vibrating films 12 having relatively small intervals with the central vibrating film 120 will be referred to as vibrating films 122 of a second periphery, and four vibrating films 12 having relatively large intervals with the central vibrating film 120 will be referred to as vibrating films 123 of a third periphery.

The vibrating films 122 of the second periphery are arranged at predetermined intervals on the periphery at predetermined intervals from the central vibrating film 120 so as to surround the vibrating films 121 of the first periphery. The vibrating films 123 of the third periphery are arranged at predetermined intervals on the periphery at predetermined intervals from the central vibrating film 120 so as to surround the vibrating films 122 of the second periphery. The most part of the main surface 11 is occupied by the central vibrating film 120, the vibrating films 121 of the first periphery, the vibrating films 122 of the second periphery, and the vibrating films 123 of the third periphery.

A plurality of electrode pads 14 are formed along a pair of sides individually extending in a horizontal direction of the main surface 11 and are formed at portions which are near four vertices of the main surface 11 having an approximate square shape in plan view and at which the vibrating films 12 are not arranged. From the plurality of electrode pads 14, wiring (not shown) is connected to the pair of electrode layers of the lower electrode layer 21 and the upper electrode layer 23 in each driving layer 20 so as to be able to supply voltages to the plurality of driving layers 20 that drive the plurality of vibrating films 12 individually. From the plurality of electrode pads 14, common wiring is connected to the plurality of driving layers 20.

The connection of wiring from the pair of electrode pads 14 to the plurality of driving layers 20 is not limited thereto, and wiring may be independently connected such that some of the plurality of vibrating films 12 formed at the main surface 11 are individually controlled. For example, wiring toward driving layers 20 for driving vibrating films 12 is common, that is wiring toward driving layers 20 for driving the vibrating films 121 of the first periphery arranged at the main surface 11 is common, wiring toward driving layers 20 for driving the vibrating films 122 of the second periphery is common, and wiring toward driving layers 20 for driving the vibrating films 122 of the third periphery is common, and wiring may be connected so as to be able to drive the films independently. In addition, wiring toward the driving layers 20 for driving the plurality of vibrating films 12 disposed at the main surface 11 may be independently connected so as to be able to drive the vibrating films 12 individually. By independently controlling at least some of the plurality of vibrating films 12 formed at the main surface 11, it is possible to provide various functions such as the interference between sound waves generated in different phases, for example.

In the transducer 1 of the fourth modified example, the most part of the main surface 11 is occupied by the plurality of vibrating films 12 due to the vibrating films 12 with an approximate disk shape of the same diameter being arranged at equal intervals d in three directions at the main surface 11. Due to this arrangement, the other vibrating film adjacent to each vibrating film 12 is located at a 6-fold rotationally symmetric position of each vibrating film 12, and therefore the vibrating films 12 can be arranged with a high density. Accordingly, the most part of the main surface 11 can be effectively used as the vibrating films 12, and the transducer 1 can generate sufficient sound volume when used as a speaker. Further, since the transducer 1 of the fourth modified example is manufactured using an MEMS technology based on a semiconductor manufacturing technology, a plurality of pieces can be fabricated at a time with high accuracy.

### Fifth Modified Example

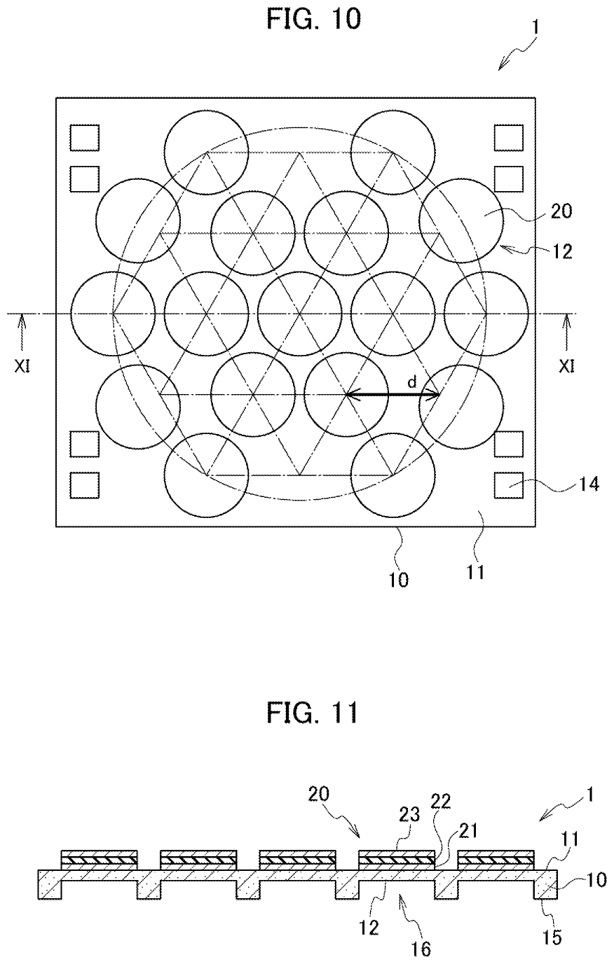

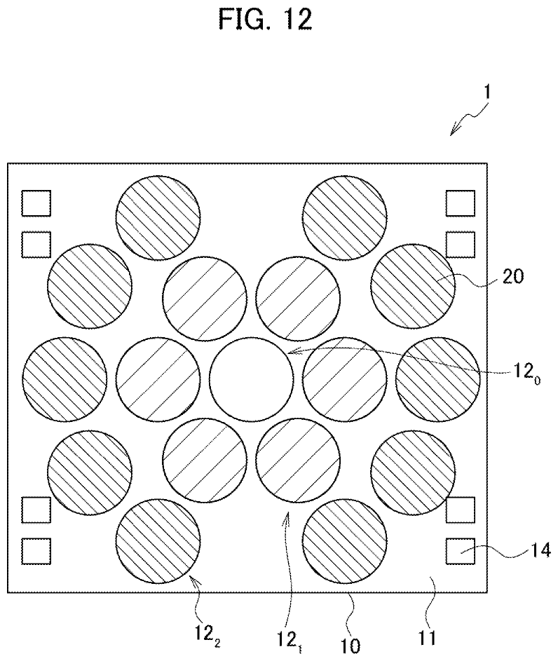

FIG. 10 is a plan view showing a transducer 1 of a fifth modified example. FIG. 11 is a cross sectional view showing the transducer 1 of the fifth modified example. The cross sectional view of FIG. 11 shows a cross section of the transducer 1 which is taken along a section line XI-XI in the plan view of FIG. 10. Compared with the transducer 1 of the present embodiment, the transducer 1 of the fifth modified example has a different arrangement of a plurality of vibrating films 12 and a plurality of electrode pads 14 at the main surface 11 of the substrate 10. Since other configurations are the same as those of the transducer 1 of the present embodiment, the corresponding members are denoted with the same reference numerals to clarify the correspondence relationship.

The transducer 1 of the fifth modified example is formed on the substrate 10 having the main surface 11 that is flat and a back surface 15 facing the main surface 11. The substrate 10 is a silicon substrate with a predetermined thickness and an approximate plate shape and has an approximate square shape in which the size in a vertical direction and the size in a horizontal direction are approximately equal in plan view. The substrate 10 is not limited to a silicon substrate, but may be a glass substrate or made of other kinds of materials such as organic material.

A plurality of recesses 16 are formed in the back surface 15 of the substrate 10. The plurality of recesses 16 are formed so as to reach a predetermined depth from the main surface 11 and leave the substrate 10 of a predetermined thickness such that the main surface 11 can vibrate in a thickness direction of the substrate 10. The portions where the substrate 10 of the predetermined thickness is left form the plurality of vibrating films 12. Since the plurality of vibrating films 12 are used to generate sound waves of speakers, natural frequencies of the vibrating films 12 are set to be higher than an audible frequency band. In addition, although the main surface 11 of the substrate 10 constituting the plurality of vibrating films 12 is connected to each of the vibrating films 12 at the whole periphery thereof, appropriate slits may be formed in the substrate 10 to achieve a structure of a cantilever beam or a double fixed beam of each vibrating film 12.

At each of the plurality of vibrating films 12, on the main surface 11, a driving layer 20 is laminated, the driving layer 20 being constituted by a pair of electrode layers of a lower electrode layer 21 and an upper electrode layer 23 with a piezoelectric layer 22 therebetween. Each driving layer 20 constitutes a piezoelectric element that drives each vibrating film 12 to vibrate in the thickness direction of the substrate 10 due to a voltage supplied by a wiring layer (not shown). At the main surface 11, the plurality of vibrating films 12 have an approximate disk shape with the same diameter. The driving layers 20 laminated on the plurality of vibrating films 12 at the main surface 11 similarly have an approximate disk shape in accordance with the shape of the plurality of vibrating films 12.

The plurality of vibrating films 12 include vibrating films 12 that are arranged at equal intervals d in three directions at the main surface 11. The intervals d of the vibrating films 12 refer to distances between centers of the vibrating films 12 having an approximate disk shape. In general, the intervals d of the vibrating films 12 may be distances between centers of gravity of the vibrating films 12 at the main surface 11. The equal intervals d are not strictly limited to equal intervals, but may be intervals that can be regarded as approximately equal, such as the difference being limited to about ±10%.

FIG. 12 is a plan view showing the arrangement of the vibrating films 12 at the main surface 11 of the substrate 10 in the transducer 1. One vibrating film 12 arranged in the center of the main surface 11 will be referred to as a central vibrating film 120. The plurality of vibrating films 12 have six vibrating films 12 that are adjacent to the central vibrating film 120 and are arranged at predetermined intervals on a periphery at predetermined intervals from the central vibrating film 120, which surrounds the central vibrating film 120. These six vibrating films 12 will be referred to as vibrating films 121 of a first periphery. The vibrating films 121 of the first periphery have a symmetry in which each of the vibrating films 121 of the first periphery is located at a 6-fold rotationally symmetric position of the central vibrating film 120 around the central vibrating film 120.

Further, the plurality of vibrating films 12 have ten vibrating films 12 arranged to surround the vibrating films 121 of the first periphery. These vibrating films 12 will be referred to as vibrating films 122 of a second periphery. Five vibrating films out of the ten vibrating films 122 of the second periphery are arranged at predetermined intervals on a periphery at predetermined intervals from the central vibrating film 120 on each of both sides close to each of vertical sides of the main surface 11 having an approximate square shape in plan view. Out of the five vibrating films 12, each of vibrating films 12 at center and both ends is located at a 6-fold rotationally symmetric position of each of the vibrating films 121 of the first periphery. The most part of the main surface 11 is occupied by the central vibrating film 120, the vibrating films 121 of the first periphery, and the vibrating films 122 of the second periphery.

A plurality of electrode pads 14 are formed along a pair of sides individually extending in a vertical direction of the main surface 11 and are formed at portions which are near four vertices of the main surface 11 having an approximate square shape in plan view and at which the vibrating films 12 are not arranged. From the plurality of electrode pads 14, wiring (not shown) is connected to the pair of electrode layers of the lower electrode layer 21 and the upper electrode layer 23 in each driving layer 20 so as to be able to supply voltages to the plurality of driving layers 20 that drive the plurality of vibrating films 12 individually. From the plurality of electrode pads 14, common wiring is connected to the plurality of driving layers 20.

The connection of wiring from the pair of electrode pads 14 to the plurality of driving layers 20 is not limited thereto, and wiring may be independently connected such that some of the plurality of vibrating films 12 formed at the main surface 11 are individually controlled. For example, wiring toward driving layers 20 for driving vibrating films 12 is common, that is wiring toward driving layers 20 for driving the vibrating films 121 of the first periphery arranged at the main surface 11 is common, and wiring toward driving layers 20 for driving the vibrating films 122 of the second periphery is common, and wiring may be connected so as to be able to drive the central vibrating film 120, the vibrating films 121 of the first periphery, and the vibrating films 122 of the second periphery independently. In addition, wiring toward the driving layers 20 for driving the plurality of vibrating films 12 disposed at the main surface 11 may be independently connected so as to be able to drive the vibrating films 12 individually. By independently controlling at least some of the plurality of vibrating films 12 formed at the main surface 11, it is possible to provide various functions such as the interference between sound waves generated in different phases, for example.

In the transducer 1 of the fifth modified example, the plurality of vibrating films 12 have a disk shape with the same diameter at the main surface 11. Further, the plurality of vibrating films 12 have vibrating films 12 arranged at equal intervals d in three directions and vibrating films 12 arranged at predetermined intervals on a periphery at predetermined intervals from the central vibrating film 120. Due to this kind of configuration of the vibrating films 12, the most part of the main surface 11 is occupied by the plurality of vibrating films 12. Therefore, the most part of the main surface 11 can be effectively used as the vibrating films 12, and the transducer 1 can generate sufficient sound volume when used as a speaker. Further, since the transducer 1 of the fifth modified example is manufactured using an MEMS technology based on a semiconductor manufacturing technology, a plurality of pieces can be fabricated at a time with high accuracy.

### Sixth Modified Example

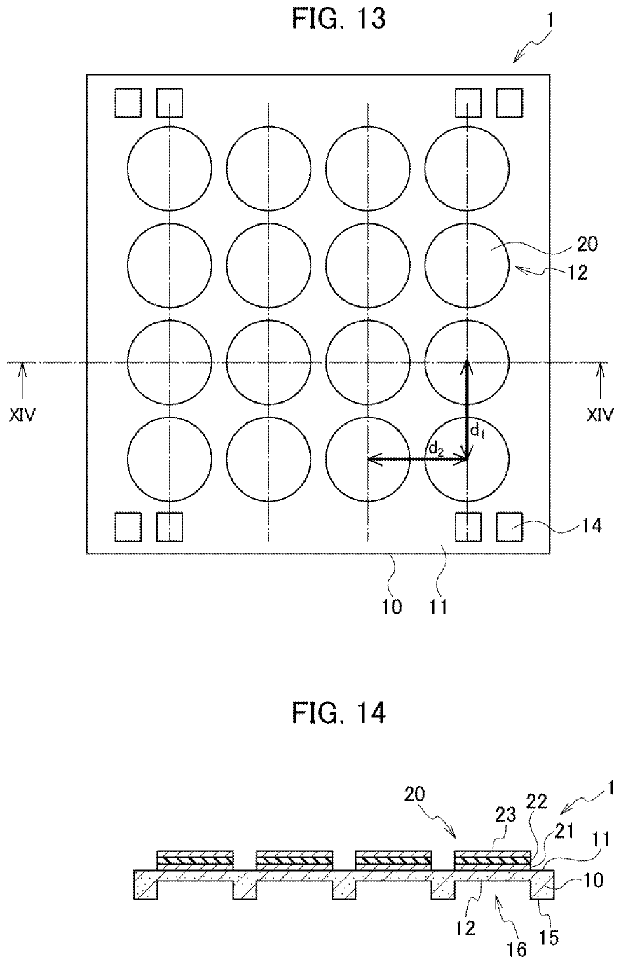

FIG. 13 is a plan view showing a transducer 1 of a sixth modified example. FIG. 14 is a cross sectional view showing the transducer 1 of the sixth modified example. The cross sectional view of FIG. 14 shows a cross section of the transducer 1 which is taken along a section line XIV-XIV in the plan view of FIG. 13. Compared with the transducer 1 of the present embodiment, the transducer 1 of the sixth modified example has a different arrangement of a plurality of vibrating films 12 and a plurality of electrode pads 14 at a main surface 11 of a substrate 10. Since other configurations are the same as those of the transducer 1 of the present embodiment, the corresponding members are denoted with the same reference numerals to clarify the correspondence relationship.

The transducer 1 of the sixth modified example is formed on the substrate 10 having the main surface 11 that is flat and a back surface 15 facing the main surface 11. The substrate 10 is a silicon substrate with a predetermined thickness and an approximate plate shape and has an approximate square shape in which the size in a vertical direction and the size in a horizontal direction are approximately equal in plan view. The substrate 10 is not limited to a silicon substrate, but may be a glass substrate or made of other kinds of materials such as organic material.

A plurality of recesses 16 are formed in the back surface 15 of the substrate 10. The plurality of recesses 16 are formed so as to reach a predetermined depth from the main surface 11 and leave the substrate 10 of a predetermined thickness such that the main surface 11 can vibrate in a thickness direction of the substrate 10. The portions where the substrate 10 of the predetermined thickness is left form the plurality of vibrating films 12. Since the plurality of vibrating films 12 are used to generate sound waves of speakers, natural frequencies of the vibrating films 12 are set to be higher than an audible frequency band. In addition, although the main surface 11 of the substrate 10 constituting the plurality of vibrating films 12 is connected to each of the vibrating films 12 at the whole periphery thereof, appropriate slits may be formed in the substrate 10 to achieve a structure of a cantilever beam or a double fixed beam of each vibrating film 12.

At each of the plurality of vibrating films 12, on the main surface 11, a driving layer 20 is laminated, the driving layer 20 being constituted by a pair of electrode layers of a lower electrode layer 21 and an upper electrode layer 23 with a piezoelectric layer 22 therebetween. Each driving layer 20 constitutes a piezoelectric element that drives each vibrating film 12 to vibrate in the thickness direction of the substrate 10 due to a voltage supplied by a wiring layer (not shown). At the main surface 11, the plurality of vibrating films 12 have an approximate disk shape with the same diameter. The driving layers 20 laminated on the vibrating films 12 similarly have an approximate disk shape in accordance with the shape of the plurality of vibrating films 12.

The plurality of vibrating films 12 include vibrating films 12 that are arranged at equal intervals in two approximately orthogonal directions at the main surface 11. That is, the equal intervals are vertical intervals d1 and horizontal intervals d2 at the main surface 11 having an approximate square shape in plan view. The intervals of the vibrating films 12 refer to distances between centers of the vibrating films 12 having an approximate disk shape. In general, the intervals of the vibrating films 12 may be distances between centers of gravity of the vibrating films 12 at the main surface 11. The vertical intervals d1 being equal intervals and the horizontal intervals d2 being equal intervals are not strictly limited to equal intervals, but may be intervals that can be regarded as approximately equal, such as the difference being limited to about ±10%.

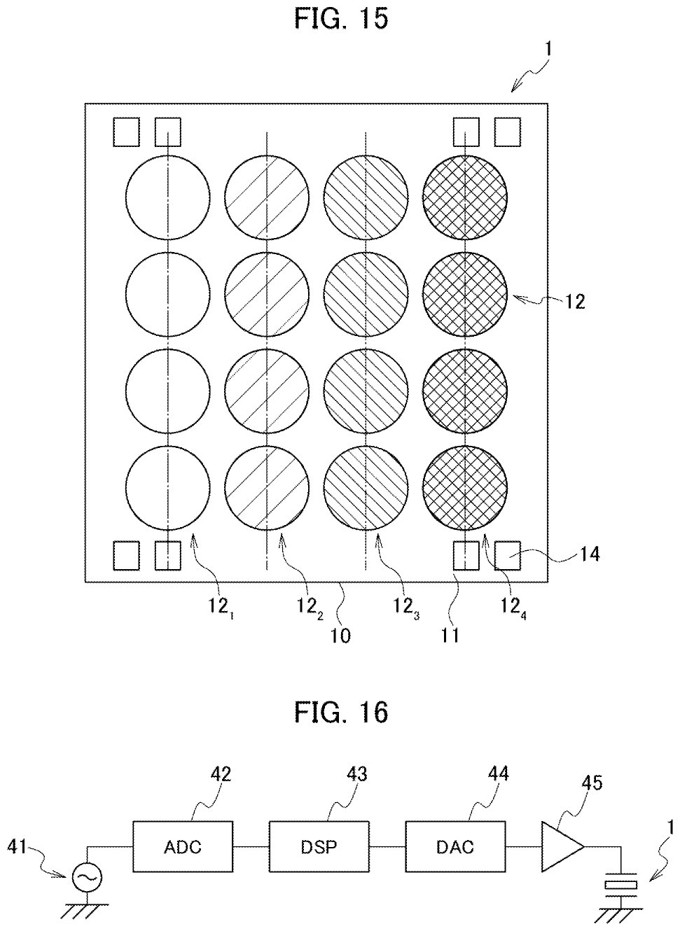

FIG. 15 is a plan view showing the arrangement of the vibrating films 12 at the main surface 11 of the substrate 10 in the transducer 1. At the main surface 11 having an approximate square shape in plan view, four vibrating films 12 are vertically arranged at the intervals d1 at positions near the left side in FIG. 15. The four vibrating films 12 will be referred to as vibrating films 121 of a first column. At the main surface 11, following the vibrating films 121 of the first column, vibrating films 122 of a second column, vibrating films 123 of a third column, and vibrating films 124 of a fourth column, in each of which four vibrating films 12 are vertically arranged similarly, are horizontally arranged in this order to a position near the right side in FIG. 15. The most part of the main surface 11 is occupied by the vibrating films 121 of the first column, the vibrating films 122 of the second column, the vibrating films 123 of the third column, and vibrating films 124 of the fourth column.

A plurality of electrode pads 14 are formed along a pair of sides individually extending in a horizontal direction of the main surface 11 and are formed at portions which are near four vertices of the main surface 11 having an approximate square shape in plan view and at which the vibrating films 12 are not arranged. From the plurality of electrode pads 14, wiring (not shown) is connected to the pair of electrode layers of the lower electrode layer 21 and the upper electrode layer 23 in each driving layer 20 so as to be able to supply voltages to the plurality of driving layers 20 that drive the plurality of vibrating films 12 individually. From the plurality of electrode pads 14, common wiring is connected to the plurality of driving layers 20.

The connection of wiring from the pair of electrode pads 14 to the plurality of driving layers 20 is not limited thereto, and wiring may be independently connected such that some of the plurality of vibrating films 12 formed at the main surface 11 are individually controlled. For example, wiring toward driving layers 20 for driving vibrating films 12 is common, that is wiring toward driving layers 20 for driving the vibrating films 121 of the first column arranged at the main surface 11 is common, wiring toward driving layers 20 for driving the vibrating films 122 of the second column is common, wiring toward driving layers 20 for driving the vibrating films 123 of the third column is common, and wiring toward driving layers 20 for driving the vibrating films 124 of the fourth column is common, and wiring may be connected so as to be able to drive the vibrating films 121 of the first column, the vibrating films 122 of the second column, the vibrating films 123 of the third column, and the vibrating films 124 of the fourth column independently. In addition, wiring toward the driving layers 20 for driving the plurality of vibrating films 12 disposed at the main surface 11 may be independently connected so as to be able to drive the vibrating films 12 individually. By independently controlling at least some of the plurality of vibrating films 12 formed at the main surface 11, it is possible to provide various functions such as the interference between sound waves generated in different phases, for example.

In the transducer 1 of the fifth modified example, at the main surface 11, the vibrating films 12 having an approximate disk shape with the same diameter are arranges at the interval d1 in the vertical direction and at the interval d2 in the horizontal direction, and accordingly the most part of the main surface 11 is occupied by the plurality of vibrating films 12. Therefore, the most part of the main surface 11 can be effectively used as the vibrating films 12, and the transducer 1 can generate sufficient sound volume when used as a speaker. Further, since the transducer 1 of the sixth modified example is manufactured using an MEMS technology based on a semiconductor manufacturing technology, a plurality of pieces can be fabricated at a time with high accuracy.

### Electronic Device

An electronic device of the present embodiment includes the transducer 1 of the present embodiment as a speaker. The electronic device of the present embodiment can generate sufficient sound volume by including the transducer 1 of the present embodiment as a speaker.

FIG. 16 is a block diagram showing the electronic device of the present embodiment. The electronic device of the present embodiment includes the transducer 1 of the present embodiment as a speaker, and further includes an analog-to-digital converter (ADC) 42, a digital signal processor (DSP) 43, a digital-to-analog converter (DAC) 44, and an amplifier 45 such that sound waves of the constant sound quality can be generated from the transducer 1 in accordance with a sound signal input from a signal source 41.

In the electronic device, a sound signal input from the signal source 41 as an analog signal is converted into a digital signal by the analog-to-digital converter 42, and then is subjected to predetermined processing by the digital signal processor 43. For example, the digital signal processor 43 compensates frequency characteristics of the transducers 1, controls a phase between transducers 1, and performs processing such as equalizer processing and surround processing when necessary. The sound signal that has been processed by the digital signal processor 43 is converted to an analog signal by the digital-to-analog converter 44 and then is amplified by the amplifier 45 to drive the transducer 1.

Since the electronic device of the present embodiment has the transducer 1 of the present embodiment as a speaker, sufficient sound volume can be generated even if a speaker is small in size. In addition, since the transducer 1 of the present embodiment is driven by a piezoelectric element with a voltage, it is possible to reduce the power consumption of the transducer 1 compared to that of an electronic apparatus including a conventional dynamic speaker. Further, since the transducer 1 in the electronic device is manufactured using an MEMS technology based on a semiconductor manufacturing technology, a plurality of pieces can be fabricated at a time with high accuracy.

### Transducer Array

A transducer array of the present embodiment uses the transducers of the present embodiment and has the plurality of transducers of which main surfaces face one side and which are arranged in a two-dimensional manner so as to include transducers arranged at predetermined intervals in each of at least two directions. Since the transducer array of the present embodiment uses the transducers of the present embodiment, sufficient sound volume can be generated. In addition, since the plurality of transducers are arranged at predetermined intervals in each of at least two directions, sound waves can be emitted such that the sound volume distribution is approximately uniform in a predetermined range on one side.

The transducers arranged at predetermined intervals in each of at least two directions may include transducers arranged at equal intervals in three directions including at least two directions in the plane defined by the two-dimensional arrangement of the transducer. The sound volume generated by the transducer array can be ensured by arranging the transducers while ensuring the density of the transducers.

A main surface of each of the plurality of transducers may incline toward the center of the plurality of transducers which are arranged in a two-dimensional manner as the distance increases from the center. The transducer array may emit sound waves such that the sound waves concentrate in the center of the front on one side.

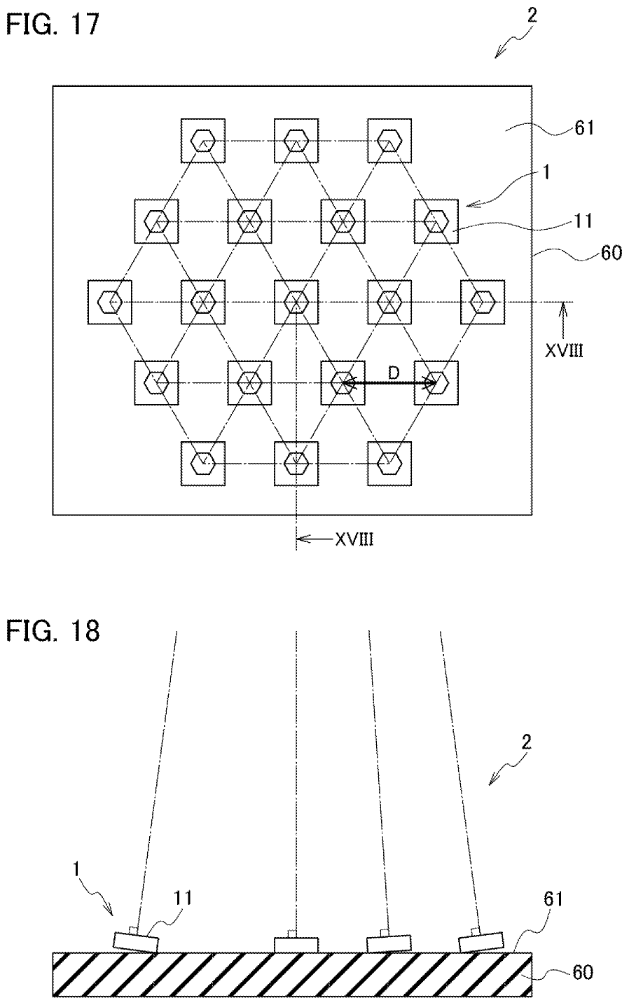

FIG. 17 is a plan view showing a transducer array 2 of the present embodiment. FIG. 18 is a cross sectional view showing the transducer array 2 of the present embodiment. The cross sectional view of FIG. 18 shows a cross section which is taken along a section line XVIII-XVIII in the plan view of FIG. 17.

In the transducer array 2 of the present embodiment, on a flat main surface 61 of a support substrate 60, the plurality of transducers 1 of the present embodiment are arranged in a two-dimensional manner such that main surfaces 11 of the transducers 1 face a side away from the main surface 61 of the support substrate 60. The plurality of transducers 1 are arranged at equal intervals D in three directions on the main surface 61, and are arranged such that each main surface 61 of each transducer 1 inclines toward the center of the support substrate 60 as the distance increases from the center of the support substrate 60. The intervals D of the transducers 1 may be distances between center positions of contours when the transducers 1 are viewed in plan view, or distances between positions of centers of gravity of vibrating films 12 formed on the main surfaces 61 of the transducers 1. The equal intervals D are not strictly limited to equal intervals, but may be intervals that can be regarded as approximately equal, such as the difference being limited to about ±10%.

The support substrate 60 with a predetermined thickness and an approximate plate shape has an approximate square shape in which the size in a vertical direction and the size in a horizontal direction are approximately equal in plan view. Similar to the substrate 10, the support substrate 60 may be a silicon substrate, made of other kinds of materials such as glass or organic materials, or may be a printed substrate.

Since the plurality of transducers 1 are arranged at equal intervals D in three directions on the main surface 61, the plurality of transducers have a symmetry in which the other transducer 1 adjacent to each transducer 1 is located at a 6-fold rotationally symmetric position of each transducer 1. Base on a central transducer 1 on the main surface 61, the plurality of transducers 1 have six transducers 1 which are arranged adjacent to and around the central transducer 1 and are located at 6-fold rotationally symmetric positions of the central transducer 1. Further, the plurality of transducers 1 have 12 transducers arranged around the six transducers 1 such that out of the 12 transducers, six transducers 1 are arranged adjacent to and around the six transducers 1 and located at 6-fold rotationally symmetric positions of the six transducers.

In the transducer array 2 of the present embodiment, the plurality of transducers 1 are arranged such that each main surface 61 of each transducer 1 inclines toward the center of the main surface 61 of the support substrate 60 as the distance increases from the center. FIG. 18 shows normal lines of the main surfaces 61 to indicate the inclination of the main surfaces 61.

In the transducer array 2 of the present embodiment, the transducers 1 are arranged such that the intervals D of the transducers 1 are equal, and therefore sound waves can be emitted from the plurality of transducers 1 to achieve the approximately uniform sound volume distribution in a certain range of the front of the main surface 61 of the support substrate 60. Further, since each main surface 61 of each transducer 1 inclines toward the center of the main surface 61 of the support substrate 60 as the distance increases from the center, sound waves can be emitted such that the sound waves concentrate in the center of the front of the main surface 61 of the support substrate 60. Furthermore, since the transducers 1 of the present embodiment can generate sufficient sound volume as speakers, the transducer array 2 of the present embodiment having the plurality of transducers 1 can also generate sufficient sound volume.

### Modified Example of Transducer Array

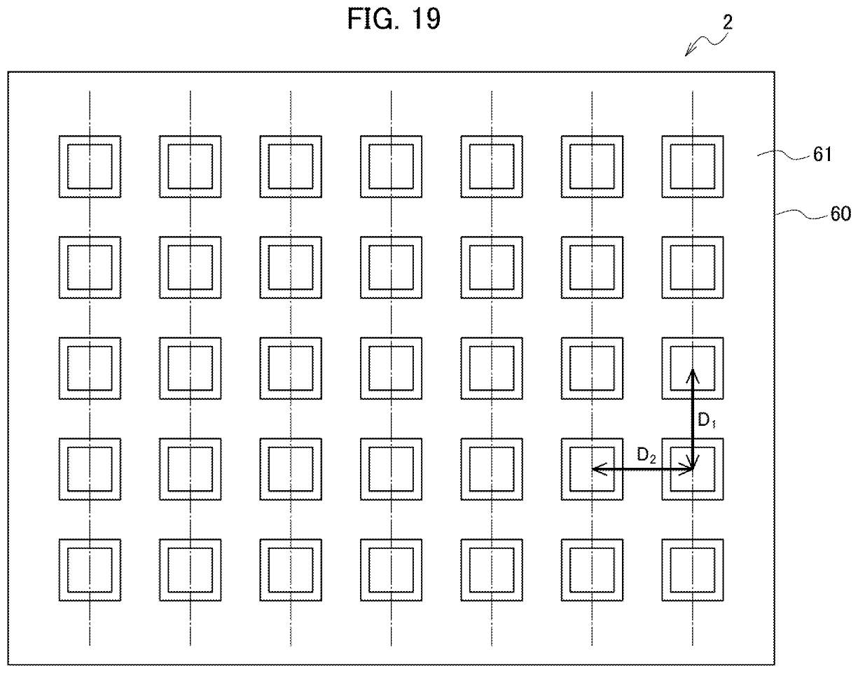

FIG. 19 is a plan view showing a transducer array 2 of a modified example. The transducer array 2 of the modified example differs from the transducer array 2 of the present embodiment in the use of the transducer 1 of the sixth modified example and the arrangement of the transducers 1. Since other configurations are the same as those of the transducer array of the present embodiment, the corresponding members are denoted with the same reference numerals to clarify the correspondence relationship.

In the transducer array 2 of the modified example, on a flat main surface 61 of a support substrate 60, the transducers 1 of the sixed modified example are arranged in a two-dimensional manner such that main surfaces 11 of the transducers 1 face a side away from the main surface 61 of the support substrate 60. Assuming that five transducers 1 vertically arranged at intervals D1 are transducers 1 of one column, transducers 1 of seven columns are horizontally arranged at intervals D2 on the main surface 61 having an approximate square shape in plan view. The transducers 1 in each column are aligned such that the longitudinal direction is a direction in which the columns extend.

The intervals D of the transducers 1 may be distances between center positions of contours when the transducers 1 are viewed in plan view, or distances between positions of centers of gravity of vibrating films 12 formed on the main surfaces 61 of the transducers 1. The most part of each main surface 61 is occupied by these transducers 1. The transducers 1 may be arranged such that each main surface 61 inclines toward the center of the support substrate 60 as the distance increases from the center of the support substrate 60.

The support substrate 60 with a predetermined thickness and an approximate plate shape has an approximate square shape in which the size in a vertical direction and the size in a horizontal direction are approximately equal in plan view. Similar to the substrate 10, the support substrate 60 may be a silicon substrate, made of other kinds of materials such as glass or organic materials, or may be a printed substrate.

In the transducer array 2 of the modified example, the transducers 1 are arranged such that the intervals D1 are equal in the vertical direction and the intervals D2 are equal in the horizontal direction. Therefore sound waves can be emitted from the plurality of transducers 1 such that the sound volume distribution is approximately uniform in a certain range of the front of the main surface 61 of the support substrate 60. Further, since the transducers 1 of the sixed modified example can generate sufficient sound volume as speakers, the transducer array 2 of the modified example having the plurality of transducers 1 can also generate sufficient sound volume. When each main surface 61 of each transducer 1 inclines toward the center of the main surface 61 of the support substrate 60 as the distance increases from the center, sound waves can be emitted such that the sound waves concentrate in the center of the front of the main surface 61 of the support substrate 60. The equal intervals for the intervals D1 in the vertical direction and the intervals D2 in the horizontal direction are not strictly limited to equal intervals, but may be intervals that can be regarded as approximately equal, such as the difference being limited to about ±10%.

The present embodiment has been described as above, but the description and drawings which form part of the disclosure are illustrative and should not be understood as limiting. Various alternative embodiments, examples, and operational techniques will be apparent to those skilled in the art from the disclosure.

For example, the transducer may be applied to a usage application for generating ultrasound waves in addition to generating sound waves. Further, the transducer may be applied to a usage applications for detecting sound waves or ultrasound waves.

What is claimed is:

1. A transducer comprising:
a substrate including a main surface and a back surface facing the main surface;
a plurality of vibrating films formed in the substrate at a predetermined thickness between the main surface and a plurality of recesses formed in the back surface of the substrate such that the main surface can vibrate in the thickness direction of the substrate; and
a plurality of driving layers laminated on the plurality of vibrating films, each being constituted by a pair of electrode layers with a piezoelectric layer therebetween and being disposed on the main surface, wherein
the plurality of vibrating films include vibrating films arranged at predetermined intervals in each of at least two directions in a plane of the main surface.

2. The transducer according to claim 1, wherein
the vibrating films arranged at the predetermined intervals in each of the at least two directions include vibrating films arranged at equal intervals in each of three directions including the at least two directions in the plane of the main surface.

3. The transducer according to claim 1, wherein
the plurality of vibrating films include vibrating films that are arranged such that an interval between mutually adjacent vibrating films is equal in the plane of the main surface.

4. The transducer according to claim 1, wherein
natural frequencies of the plurality of vibrating films are higher than an audible frequency band.

5. The transducer according to claim 1, wherein
the plurality of vibrating films include vibrating films having the same shape in the plane of the main surface.

6. The transducer according to claim 1, wherein
wiring is connected to the pair of electrode layers in each of the plurality of driving layers from an electrode pad such that a voltage for driving the driving layers is supplied.

7. The transducer according to claim 6, wherein
the wiring includes common wiring toward the pair of electrode layers in each of the plurality of driving layers.

8. The transducer according to claim 6, wherein
the plurality of vibrating films include vibrating films with equal intervals from one vibrating film in the plane of the main surface.

9. The transducer according to claim 8, wherein
the vibrating films with the equal intervals from the one vibrating film include vibrating films that are arranged at predetermined intervals along a periphery that is at predetermined intervals from the one vibrating film.

10. The transducer according to claim 9, wherein
the vibrating films include vibrating films that are arranged at predetermined intervals along a second periphery at predetermined intervals from the one vibrating film, the second periphery being located outside of a first periphery which is at predetermined intervals from the one vibrating film and along which vibrating films are arranged at predetermined intervals.

11. The transducer according to claim 10, wherein
the plurality of vibrating films include vibrating films having the same shape of each periphery in the plane of the main surface.

12. The transducer according to claim 10, wherein
the wiring includes wiring common to vibrating films disposed along each periphery.

13. The transducer according to claim 1, wherein
on the back surface, a partition wall is formed from the back surface to a predetermined height around each of the recesses on each vibrating film of the plurality of vibrating films to form an independent space.

14. The transducer according to claim 1, wherein
on the main surface, a partition wall is formed from the main surface to a predetermined height around each vibrating film of the plurality of vibrating films to form an independent space.

15. The transducer according to claim 1, wherein
the substrate is constituted by a silicon substrate.

16. The transducer according to claim 1, further comprising:
another substrate that is disposed to face the back surface and is mounted near the back surface of the substrate.

17. An electronic device comprising:
the transducer according to claim 1 as a speaker.

18. A transducer array using the transducer according to claim 1, wherein
the transducer is provided in plurality, main surfaces of the plurality of transducers face one side, and the plurality of transducers are arranged in a two-dimensional manner so as to include transducers arranged at predetermined intervals in each of at least two directions.

19. The transducer array according to claim 18, wherein
the transducers arranged at the predetermined intervals in each of the at least two directions include transducers arranged at equal intervals in three directions including the at least two directions in a plane defined by the transducers which have been arranged in the two-dimensional manner.

20. The transducer array according to claim 18, wherein
a main surface of each of the plurality of transducers inclines toward a center of the plurality of transducers which have been arranged in a two-dimensional manner as a distance increases from the center.
